(19) United States
(12) Patent Application Publication
(10) Pub. No.: US 2014/0034972 A1
(43) Pub. Date: Feb. 6, 2014

(54) HOUSING FOR HIGH-POWER LIGHT EMITTING DIODES

(71) Applicants: Robert Hettler, Kumhausen (DE); Matthias Rindt, Landshut (DE)

(72) Inventors: Robert Hettler, Kumhausen (DE); Matthias Rindt, Landshut (DE)

(73) Assignee: SCHOTT AG, Mainz (DE)

(21) Appl. No.: 14/003,925

(22) PCT Filed: Mar. 5, 2012
(86) PCT No.: PCT/EP2012/000974

§ 371 Date: Oct. 15, 2013

(30) Foreign Application Priority Data
Mar. 7, 2011 (DE) 10 2011 013 277.5

(51) Int. Cl. H01L 33/48; H01L 33/64

(52) U.S. Cl. CPC H01L 33/48; H01L 33/64
USPC 257/81; 257/99; 257/433; 438/22; 438/57; 174/548

(57) ABSTRACT

A housing for optoelectronic components, such as LEDs, and to a method for producing such a housing are provided. The housing has a base body with an upper surface that at least partially defines a mounting area for at least one optoelectronic functional element, such that the base body provides a heat sink for an optoelectronic functional element. The base body also has a lower surface and a lateral surface. The housing has a connecting body for the optoelectronic functional element, which is joined to the base body at least by a glass layer. The connecting body is arranged at a lateral side of the base body and at least partially extends around a periphery of the base body.

### FIELD OF THE INVENTION

The present invention relates to a housing for optoelectronic components such as LEDs, and to a method for manufacturing such a housing.

### BACKGROUND OF THE INVENTION

It is common practice nowadays to encapsulate so-called high-power light emitting diodes (LEDs) in plastic and resin structures, i.e. in organic housings. However, an LED disposed in such a housing is not sufficiently hermetically encapsulated from possible environmental influences. This may lead to a degradation of materials, surfaces, and/or electrical connections. In addition, the thermal resistance of the resin has been found to be problematic in case of high-output optoelectronic components, e.g. 5 W LEDs.

A technology to overcome these drawbacks has been described in patent application WO 2009/132838 A1. The contents of this patent application is fully incorporated in the present patent application by reference. A substantially fully inorganic housing is described therein, which is a housing comprising a composite structure of a metallic base part and a metallic head part disposed on the upper surface of the base part. These parts are joined together by means of a glass layer. An optoelectronic functional element is positioned upon the base part. The head part above the base part forms a reflector for radiation emitted from or for radiation to be received by the optoelectronic functional element, inter alia. When joining the base part, the glass layer, and the head part, the glass layer is heated until the glass reaches a viscosity at which the glass adheres and the base part and the head part form a composite structure by means of the first glass layer. The housing described therein has proved to be very advantageous. In particular the glass joint allows to produce a hermetic encapsulation with enhanced temperature resistance. This technology permits to economically produce small housings with the aforementioned advantages.

### General Description of the Invention

Given the prior art background described above, an object of the present invention is to provide an alternative housing for optoelectronic components, especially for high-power LEDs, and an alternative method for manufacturing such a housing.

In particular it is intended to provide for a compact housing of small dimensions.

These objects are already achieved by the housing for accommodating an optoelectronic functional element and by the method for manufacturing such a housing according to the independent claims. Advantageous embodiments of the housing according to the invention and of the method according to the invention are set forth in the respective dependent claims.

The present invention provides a housing for accommodating an optoelectronic functional element, in particular an LED, which at least consists of the following constituents or comprises the following constituents. The housing according to the invention is a housing comprising:
a base body having an upper surface which at least partially defines a mounting area for at least one optoelectronic functional element so that the base body forms a heat sink for at least one optoelectronic functional element, and further having a lower surface, and a lateral surface; and
at least one connecting body for at least one optoelectronic functional element, which is joined to the base body at least by one glass layer, preferably through a material bond;
wherein the at least one connecting body is arranged and/or attached at the lateral side of the base body, and at least partially extends along the lateral surface of the base body around the periphery of the base body; and/or
wherein at least the upper surface of the base body has at least one first depression with a bottom that provides the mounting area for at least one optoelectronic functional element.

Furthermore within the scope of the invention is a method for producing an optoelectronic functional element housing, in particular for an LED, comprising the method steps of:
providing at least one base body having an upper surface which at least partially defines a mounting area for at least one optoelectronic functional element, so that the base body forms a heat sink for at least one optoelectronic functional element;
providing at least one connecting body for at least one optoelectronic functional element, and at least one glass between the base body and the connecting body for joining the connecting body to the base body;
combining the base body, the connecting body, and the glass; and
heating the glass until it has and/or reaches a viscosity at which it adheres, such that a composite can be formed from the base body and the connecting body;
cooling the glass, so that the base body and the connecting body form a material bond through at least one glass layer formed of the cooled glass;
wherein the connecting body is attached to a lateral surface of the base body, at least sections thereof, by providing the glass between the lateral surface of the base body and the connecting body, at least in sections thereof; and/or
wherein at least one first depression (11) is provided at least in the upper surface of the base body, wherein the depression has a bottom which provides the mounting area for at least one optoelectronic functional element.

In a preferred embodiment of the method, the base body and/or the connecting body and/or the glass layer and/or the glass forming the glass layer is/are provided in form of a respective array. The housing of the invention is in particular producible or produced by the method according to the invention. The method according to the invention is preferably adapted for producing the housing of the invention. The sequence of the individual method steps may vary.

Preferably, the housing according to the invention is a substantially inorganic housing. It consists of or comprises a base body made of metal, a connecting body made of metal, and the glass layer.

The at least one functional element is or has been disposed upon the base body. On the one hand, the base body constitutes a supporting member for the functional element. Therefore, the base body may also be referred to as a carrier or base. On the other hand, the base body constitutes a heat sink for the functional element.

The base body may be formed in one piece or of segments, and may for example consist of layers. Also, conductor passageways, i.e. so-called thermal vias, may be formed in the base body. After having been installed in the housing or placed upon the base body, the functional element is in direct contact with the base body.

The functional element may for example be glued to and/or soldered to the base body. As a solder, lead-free soft solders are preferably used. An adhesive that may be used is preferably a conductive adhesive such as an epoxy enriched with silver. Thus, the wording direct contact also refers to a contact via an adhesive, a solder, or a binding agent.

Since according to the invention the base body also constitutes a heat sink for the functional element, it comprises materials that exhibit appropriate thermal conductivity. Preferably, the base body has a thermal conductivity of at least about 50 W/mK, preferably at least about 150 W/mK.

The base body may be thermally coupled to other components. Preferably, the base body comprises at least one metal or is made of a metal or an alloy. A common metal, for example, is copper and/or aluminum and/or nickel and/or iron and/or molybdenum and/or copper-tungsten and/or Cu-molybdenum.

Generally, in a plan view of the upper surface, the base body has a surface area from about 9 mm² to about 400 mm², preferably of not more than about 50 mm². Its height generally ranges from about 0.1 mm to about 10 mm, preferably up to about 2 mm.

For other possible embodiments of the base body, reference is made to the base part described in document WO 2009/132838 A1.

The mounting area for the at least one functional element, usually, is in the center of the first depression. If only one functional element is to be accommodated in the housing, the mounting area is in the region of the central axis or at the central axis of the base body.

The functional element is placed in the first depression of the base body. The cross section of the depression depends on the size of the functional element and/or on the number of functional elements which is/are to be accommodated in the first depression, and/or on the number of first depressions in the base body. In a plan view to the upper surface of the base body, the first depression may have a surface area from about 4 mm² to about 1000 mm², or from about 4 mm² to about 50 mm², preferably up to about 20 mm². The depth thereof is generally selected such that the functional element positioned in the first depression may substantially entirely immerse in the first depression. The depth of the first depression generally ranges from about 0.2 mm to about 2 mm.

In one embodiment, the first depression has a diameter that increases starting from the bottom of the first depression onto which at least one optoelectronic functional element is positionable, towards the upper side of the first depression. The first depression may at least partly be in shape of a truncated cone or a truncated pyramid. This configuration allows to improve the emitting and/or receive characteristics of the housing for light or, more generally, for radiation.

Preferably, for this purpose, an inner surface or lateral surface of the first depression in the base body and/or additionally also an inner surface of a transmission zone in the connecting body, which will be explained below, has/have reflecting properties, at least sections thereof. Thus, the first depression in the upper surface of the base body and/or the transmission zone in the connecting body may form a reflector for the radiation emitted and/or to be received by an optoelectronic functional element.

The at least one connecting body is a connecting body for providing an electrical connection for the functional element placed on the upper surface of the base body, preferably in the first depression. Generally, the connecting body permits to establish a connection between the upper surface of the base body and thus the functional element and the surroundings.

The connecting body is a solid body. It is in particular also provided as a metal plate. Preferably, it may even be deformable under slight pressure, for example when being compressed with the fingers. It does however not constitute a layer deposited or grown on the base body, for example using a PVD process.

The connecting body is electrically insulated from the base body. It is separated by the glass layer, at least sections thereof, and/or it is arranged spaced apart from the base body, at least sections thereof.

The connecting body comprises or is made up of a metal or an alloy. The metal in this case is at least one selected from the group consisting of copper, aluminum, nickel, cobalt, iron, steel or stainless steel, ferritic steel or stainless steel, and austenitic steel or stainless steel. Usually, the connecting body has a surface area, in a plan view of the upper surface thereof, from about 9 mm² to about 1000 mm², preferably up to about 50 mm². Its height generally ranges from about 0.1 mm to about 5 mm, preferably up to about 2 mm.

For other possible embodiments of the connecting body, reference is made to the head part described in document WO 2009/132838 A1.

In a preferred embodiment of the invention, the connecting body provides a transmission zone for radiation emitted and/or to be received by at least one optoelectronic functional element. The transmission zone extends over the range of the first depression and/or the mounting area for at least one optoelectronic functional element and/or over the base body, at least over sections thereof. The transmission zone may represent a region through which light or radiation may pass, i.e. may enter and/or exit.

The transmission zone is preferably configured as a recess or a hole in the connecting body. The light may be incident to the lateral surface of the recess. Preferably, the transmission zone is arranged coaxially to the base body and/or to the first depression. In a plan view to the upper surface of the base body, the transmission zone may have a surface area from about 4 mm² to about 1000 mm², or from about 4 mm² to about 50 mm², preferably up to about 20 mm². The depth thereof substantially corresponds to the height of the connecting body.

In a preferred embodiment of the housing, the upper surface of the base body has a second depression, which extends around the periphery of the first depression, at least sections thereof, so that the lateral surface of the base body is formed by at least a preferably lower outer lateral surface and a preferably upper inner lateral surface. So some kind of a step is formed in the base body or in the upper surface of the base body. The outer lateral surface of the base body preferably corresponds to the actual lateral surface of the base body. The outer lateral surface is at a greater distance from the center of the first depression or of the base body than the inner lateral surface. The base body has an upper surface and a lower surface. The lateral surface herein represents the lateral wall surface connecting the upper surface with the lower surface.

The second depression constitutes an accommodating region for the connecting body. The connecting body at least partially rests upon the bottom of the second depression, in particular the lower surface thereof. Alternatively or additionally, the connecting body may adjoin the inner and/or outer lateral surface of the base body. In particular, the lateral surface of the connecting body, especially the lateral surface of the transmission zone, is adjacent to the inner and/or outer lateral surface of the base body. Thus, the connecting body is arranged at least partially upon the upper surface of the base body, and/or an inner side of the transmission zone is arranged adjacent to the inner lateral surface and/or adjacent to the outer lateral surface of the base body.

Generally, in a plan view of the upper surface of the base body, the width of the second depression ranges from about 0.5 mm to about 15 mm, preferably up to about 6 mm. The width of the depression is defined by the support surface for the connecting body on the base body. The depth of the second depression generally ranges from about 0.1 mm to about 5 mm.

Since, usually, the base body and the connecting body are electrically insulated from each other, to be ‘arranged adjacent to’ also refers to an arrangement wherein the base body and the connecting body are separated by a glass layer. In the embodiment mentioned first, the glass layer is arranged between a bottom of the second depression and the lower surface of the connecting body, at least in sections thereof. In the second embodiment, the glass layer is arranged between the inner lateral surface of the connecting body, preferably of the transmission zone, and the outer lateral surface of the base body.

In another embodiment, the connecting body is segmented. By virtue of the segments formed, a plurality of terminals can be provided for a plurality of optoelectronic functional elements or for a single optoelectronic functional element positioned upon the base body. Preferably, the segments of the connecting body are spaced apart from each other and/or electrically insulated from each other by the glass layer.

In another embodiment of the housing, the connecting body extends beyond the base body, at least portions thereof, and provides at least one connection tab. The tab is preferably manually bendable and/or has a width which decreases radially outwards, in particular continuously. The tab enlarges the connecting body. Usually in this case, in a plan view of its upper surface the connecting body will have a surface area from about 9 mm² to about 800 mm², preferably up to about 100 mm².

Furthermore, a mounting region for a connecting means, preferably for a bonding wire, may be provided in or at the base body and/or in or at the connecting body. The mounting region is preferably formed as a recess in the inner periphery of the first depression and/or of the transmission zone.

The glass is a glass for joining the base body to the connecting body and/or for insulating the base body from the connecting body. The glass has a softening point or softening temperature in a region below the melting temperature of the materials used for the base body and/or for the connecting body. For joining or upon joining, the glass is or has been heated to an extent to have a viscosity at which the components adhere to each other. Upon joining, the glass preferably has a viscosity in a range from 10⁷ Pa·s to about 10³ Pa·s. Heating is accomplished in a furnace, for example. The employed glass preferably is or comprises a phosphate glass and/or a soft glass and/or an alkali titanium silicate glass. Examples of a phosphate glass include the glasses designated SCHOTT G018-122. Examples of a soft glass include the glasses designated SCHOTT 8061 and/or SCHOTT 8421.

If, for example, the base body and/or the connecting body substantially comprise copper and/or aluminum, in particular at the boundary surface(s) to the glass, the glass is preferably an alkali titanium silicate glass. The base body and/or the connecting body and/or at least the respective boundary surface(s) has/have a copper or aluminum content of at least 50 wt. %, preferably of at least 80 wt. %.

In one embodiment, the alkali titanium silicate glass has or comprises the following composition (in percent by weight):

| | |
|---|---|
| SiO₂ | 20-50 |
| TiO₂ | 10-35 |
| R₂O | 10-40 |
| Al₂O₃ | 0-5 |
| CaO + SrO | 0-5 |
| P₂O₅ | 0-5 |
| V₂O₅ | 0-5 |
| B₂O₃ | 0-5 |
| Sb₂O₃ | 0-1 |
| SnO₂ | 0-5 |
| Fe₂O₃ | <1 |
| CoO | <1 |
| NiO | <1 |
| ZnO | 0-4 |
| ZrO₂ | 0-4 |
| F | 0-2 |
| MoO₃ | 0-1 |
| N₂O₅ | 0-6 |
| SO₃ | 0-1 |

The term R₂O as used in the table represents the sum of all alkali oxides. The alkali metals therein are provided at least by elements Li, Na, and K.

In one specific embodiment, the R₂O group includes the following components (in percent by weight):

| | |
|---|---|
| Na₂O | 11-22 |
| K₂O | 8-17 |
| Li₂O | 0.2-3 |

In a first preferred embodiment, the glass has or comprises the following composition:

| | |
|---|---|
| SiO₂ | 26-30 |
| TiO₂ | 21-25 |
| Na₂O | 14-18 |
| K₂O | 11-15 |
| Li₂O | >0-3 |
| Al₂O₃ | >1-5 |
| CaO | >0-1 |
| SrO | 0-1 |
| P₂O₅ | >0-3 |
| B₂O₃ | >0-4 |
| Fe₂O₃ | >0-2 |
| CoO | 0-1 |
| NiO | 0-1 |
| ZnO | >0-2 |
| ZrO₂ | >0.5-2 |

Preferably, the glass of the first embodiment has or comprises the following composition:

| | |
|---|---|
| SiO₂ | 28 |
| TiO₂ | 23 |
| Na₂O | 16 |
| K₂O | 13 |
| Li₂O | 1.12 |
| Al₂O₃ | 3.4 |
| CaO | 0.2 |
| SrO | 0.02 |
| P₂O₅ | 1.6 |
| B₂O₃ | 2 |
| Fe₂O₃ | 0.2 |
| CoO | 0.03 |
| NiO | <0.02 |
| ZnO | 0.2 |
| ZrO₂ | 0.9 |

In a second preferred embodiment, the glass has or comprises the following composition:

| | |
|---|---|
| SiO₂ | 36-40 |
| TiO₂ | 24-28 |
| Na₂O | 15-19 |
| K₂O | 10-14 |
| Li₂O | >0-3 |
| Al₂O₃ | 1-6 |
| CaO | >0-1 |
| SrO | <1 |
| P₂O₅ | >0-4 |
| B₂O₃ | >0-2 |
| Fe₂O₃ | 0-2 |
| CoO | <1 |
| NiO | <1 |
| ZnO | <1 |
| ZrO₂ | <1 |

Preferably, the glass of the second embodiment has or comprises the following composition:

| | |
|---|---|
| SiO₂ | 38 |
| TiO₂ | 26 |
| Na₂O | 17 |
| K₂O | 11.6 |
| Li₂O | 1.22 |
| Al₂O₃ | 3.7 |
| CaO | 0.3 |
| P₂O₅ | 1.6 |
| B₂O₃ | 0.29 |
| Fe₂O₃ | 0.08 |
| CoO | |
| NiO | <0.02 |
| ZnO | 0 |
| ZrO₂ | 0.1 |

The glass layer formed by the glass, or in more detail the glass layer formed between the base body and the connecting body generally has a thickness of more than about 30 μm. This permits to provide a gas-tight bonding with sufficient electrical insulating properties. Preferably, the thickness of the glass layer ranges from about 30 μm to about 500 μm, more preferably from about 100 μm to about 300 μm.

The electrical resistance of the glass layer based on an alkali titanium silicate glass, especially with the aforementioned compositions, is generally greater than 1 GΩ. Gas tightness is generally less than 1*10⁻⁸ mbar*l/s. Furthermore, the glass is distinguished by an improved strength and improved chemical resistance. For example, the shear strength in a sample body (4 mm×4 mm of glazing surface, and 100 μm of nominal thickness of the glass layer) can be increased with the glass of the invention from an average of 60 N to 105 N, as compared to the glass P8061. Furthermore, the glass according to the invention has an improved chemical resistance as compared to the glass G018-122 (see WO 2009/132838 A1). Electro-plating may be performed after vitrification.

Generally, the glass may be applied by at least one method selected from a group consisting of dispensing, providing of a preferably punched glass strip, and/or providing of an individual preform. A glass strip may for example be provided by molding slip into a strip shape. For economic manufacturing, the glass may be provided in an array.

For other possible embodiments of the glass layer and the methods of using a glass layer, reference is made to the first and/or second glass layers described in document WO 2009/132838 A1.

The glass layer is arranged between the lateral surface of the base body and the connecting body, at least in sections thereof. Preferably, the glass layer is at least partially arranged between the lateral surface of the base body and the lateral surface of the connecting body, preferably of the transmission zone thereof.

In an alternative or additional embodiment, the glass layer is arranged between the upper surface of the base body and a lower surface of the connecting body, at least in sections thereof.

In order to achieve better adherence of the connecting body to the base body, the glass contacting surfaces of the base body and/or the connecting body are preferably pretreated. In one embodiment, the pre-treatment may comprise a pre-oxidation of the glass contacting surfaces. Pre-oxidation refers to a selective oxidation of a surface, for example in an oxygen-containing atmosphere. In this case, a bonding between glass and copper or copper oxide has proved to be very stable. The metal, preferably copper, is selectively oxidized in an oxygen-containing atmosphere. In terms of oxide weight, a mass per unit area from about 0.02 to about 0.25 mg/cm², preferably from about 0.067 to about 0.13 mg/cm², has proved to be advantageous for the oxide weight. The oxide adheres well and does not flake. This is particularly true when the copper is provided in a proportion of more than 50 wt. %, preferably more than 80 wt. %, in the base body and/or in the connecting body and/or at least at the interfaces.

To improve the properties of the base body and/or the connecting body, for example reflectivity, bondability and/or electrical conductivity, these bodies may be coated and/or covered, preferably at least partially, preferably with a metal. One possible method is plating, preferably electro-plating.

The optoelectronic functional element that can be positioned upon the base body, is a radiation emitting and/or radiation receiving component. Preferably, it is formed as a chip. The functional element is at least one component selected from the group of LED, photodiode, and laser diode. The housing according to the invention is particularly suitable to be used for high-power LEDs, preferably of a power of more than about 5 W, since such components require efficient heat dissipation and the housing must be sufficiently heat resistant. The housing of the invention may in particular also be useful for non-optoelectronic functional elements, such as power semiconductors, which require sufficient thermal stability when employed. Thus, the housing of the invention may also be a housing for an optoelectronic functional element and/or more generally for a functional element. The same applies to the method according to the invention.

In a further modification, the housing of the invention has an accommodating area for receiving and/or supporting an end element, such as e.g. an optical component, in the upper surface of the connecting body and/or in the upper surface of the base body.

Optionally, at least one preferably transparent end element is applied to or arranged on the upper surface of the base body and/or the upper surface of the connecting body, and here preferably in the accommodating area. In particular, the end element is an optical component. One example of the optical component is a focusing component, preferably a lens. The lens may be provided by a preferably convex glass lens and/or by a drop, such as a silicone drop.

In another embodiment of the housing, an insulation is applied at least to the lower surface thereof. To this end, an insulation is provided on the lower surface of the base body and optionally on the lower surface of the connecting body, which insulation is preferably provided by an insulating layer. The insulation may be continuous or segmented. The insulation material preferably is or comprises a glass and/or a ceramic material. The layer may be applied, for example, by enameling and/or by a cold spray process. This permits to keep the lower surface of the housing electrically floating.

In another embodiment of the housing, a sleeve is arranged at the lateral side of the base body. The sleeve or sheath preferably extends around the periphery of the base body and/or the connecting body, at least around sections thereof. The sleeve is preferably secured to the base body and/or to the connecting body through the or a glass layer. The glass layer is disposed between the base body and the sleeve. Preferably, the sleeve is provided as a metallic sleeve, for example of stainless steel. This permits to provide at least the outer surface of the housing at a defined potential, for example ground potential.

The base body, in particular including the first and/or a second depression and/or other modifications, and/or the connecting body, in particular including the transmission zone and/or the tab and/or other modifications, is/are produced by a lead frame process. Examples of such a manufacturing technique include photochemical etching, punching, laser cutting, and/or water jet cutting. Punching is very cost efficient and therefore it is the preferred technique for producing the aforementioned components. Therefore, one preferred embodiment of the invention essentially uses only punchable metals for producing the base body and/or the connecting body. In one embodiment, a plate is patterned in a manner such that a multitude of components is obtained per plate. The housing is part of an array of individual housings. Thus, an array is some kind of a basic body in which the respective components are integrated or arranged. Therefore, likewise within the scope of the present invention is an arrangement or an array which comprises a plurality of housings, preferably the housings described above. The individual housings are attached to the respective array by webs or connecting webs. Therefore, the invention may likewise be described by a method for producing a plurality of optoelectronic functional element housings. After manufacturing thereof, the housings are separated from the array.

Furthermore within the scope of the invention is an optoelectronic component comprising a housing according to the invention and at least one radiation emitting and/or radiation receiving optoelectronic functional element, in particular an LED, which is arranged in the housing.

Also within the scope of the present invention is an illumination device, for example an interior lighting and/or exterior lighting, which comprises at least one housing and/or one optoelectronic component according to the present invention, in particular for use in a vehicle and/or an aircraft and/or as an airfield lighting. Examples of the illumination device include a seat lighting; a reading light; a work light that may especially be integrated in ceilings or walls; an object lighting in furniture and/or buildings; a headlamp and/or rear light, and/or interior lighting, and/or an instrument or display lighting, preferably in motor vehicles; a backlight for LCD displays; a UV light, preferably in medical and/or water purification applications; and/or a lighting for a harsh environment such as when exposed to moisture and/or aggressive gas and/or radiation.

The present invention will now be explained in detail by way of the following exemplary embodiments. For this purpose, reference is made to the accompanying drawings. The same reference numerals in the various drawings designate the same parts.

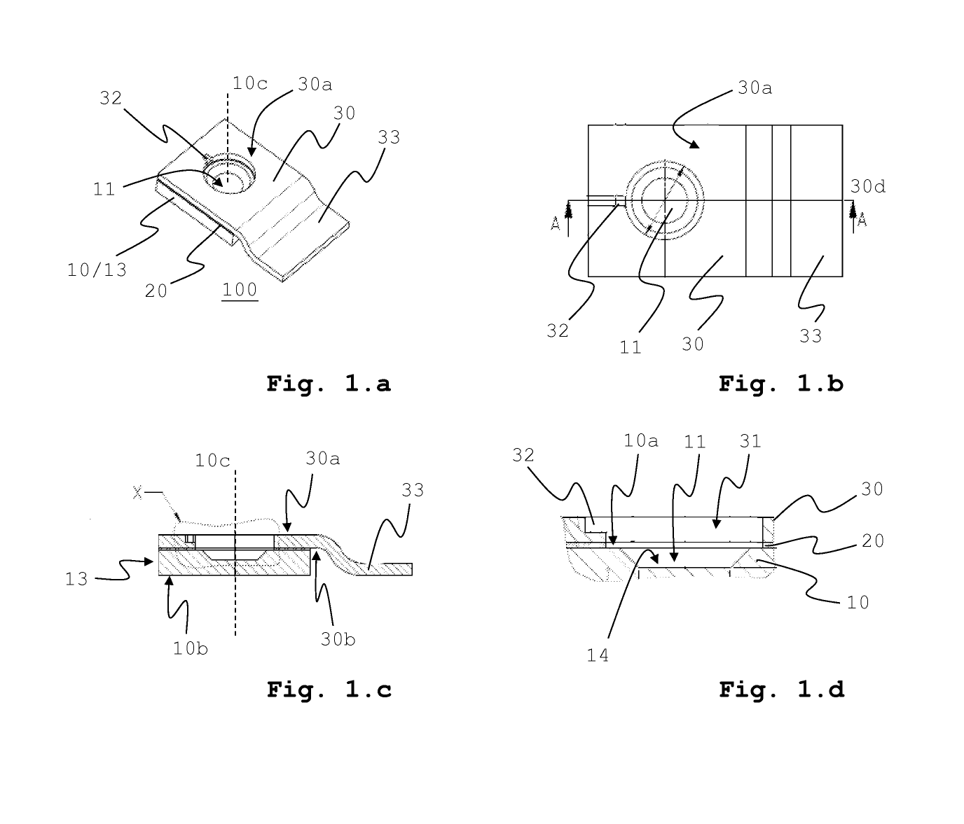

FIGS. 1.a to 1.d illustrate a first embodiment of a two-layered housing having a first depression in the base body, in a perspective view of the upper surface (FIG. 1.a), a plan view of the upper surface (FIG. 1.b), a cross-sectional view along longitudinal axis A-A (FIG. 1.c), and in an enlarged cross-sectional view of the region marked with X (FIG. 1.d).

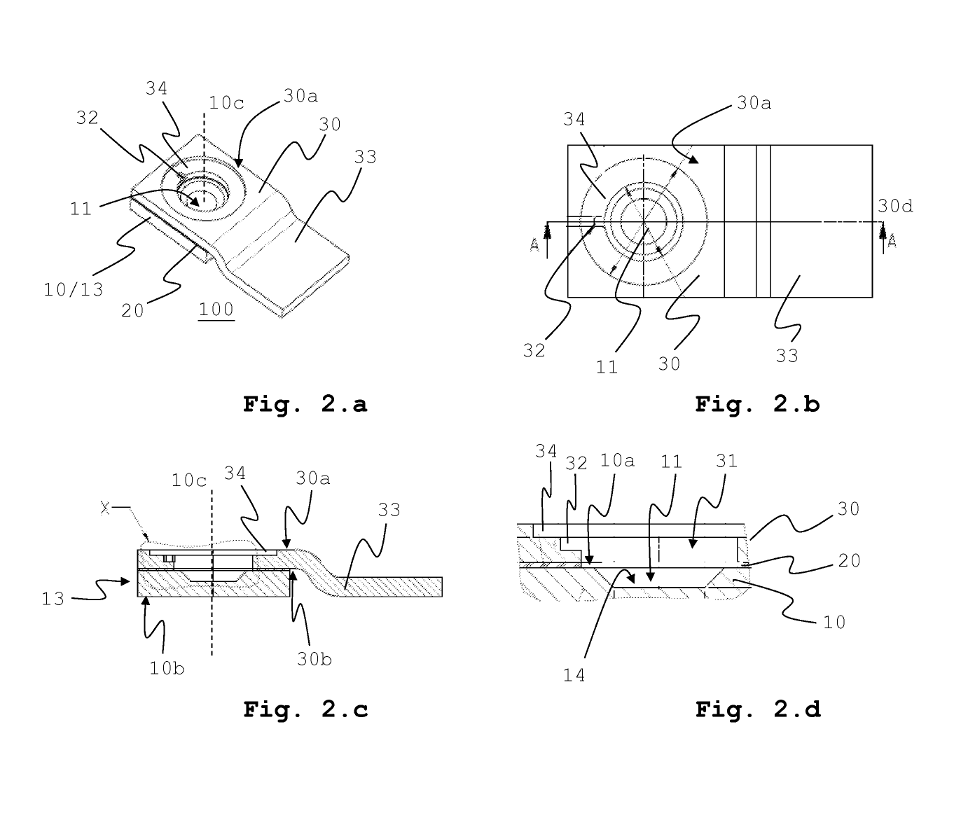

FIGS. 2.a to 2.d illustrate a second embodiment of a two-layered housing having a first depression in the base body, in a perspective view of the upper surface (FIG. 2.a), a plan view of the upper surface (FIG. 2.b), a cross-sectional view along longitudinal axis A-A (FIG. 2.c), and in an enlarged cross-sectional view of the region marked with X (FIG. 2.d).

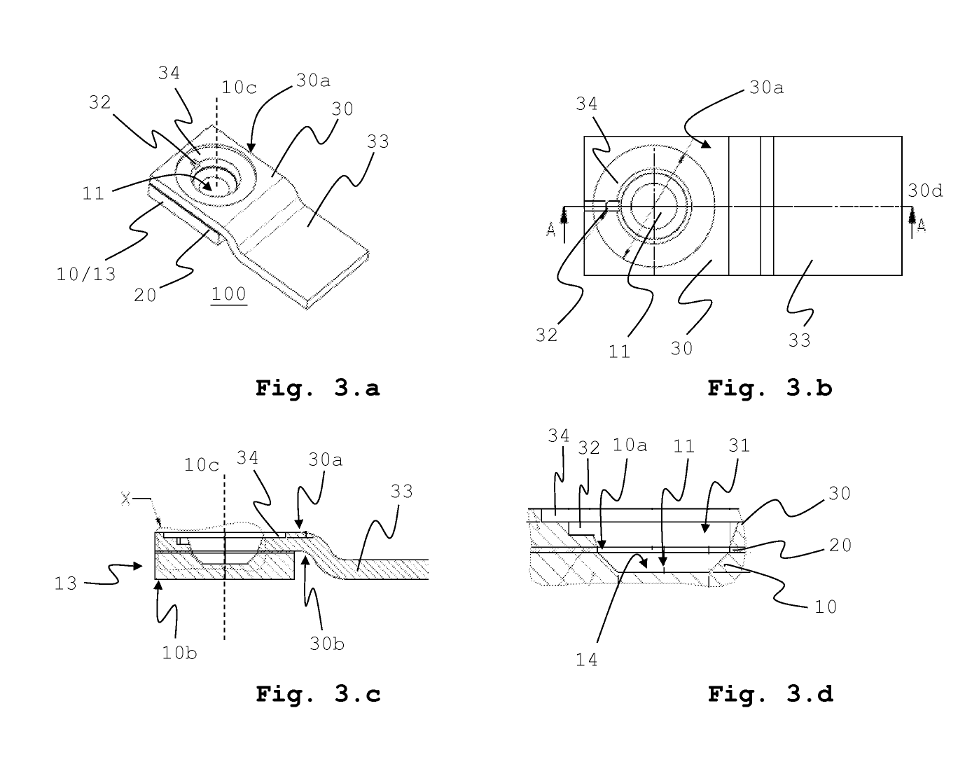

FIGS. 3.a to 3.d illustrate a third embodiment of a two-layered housing having a first depression in the base body, in a perspective view of the upper surface (FIG. 3.a), a plan view of the upper surface (FIG. 3.b), a cross-sectional view along longitudinal axis A-A (FIG. 3.c), and in an enlarged cross-sectional view of the region marked with X (FIG. 3.d).

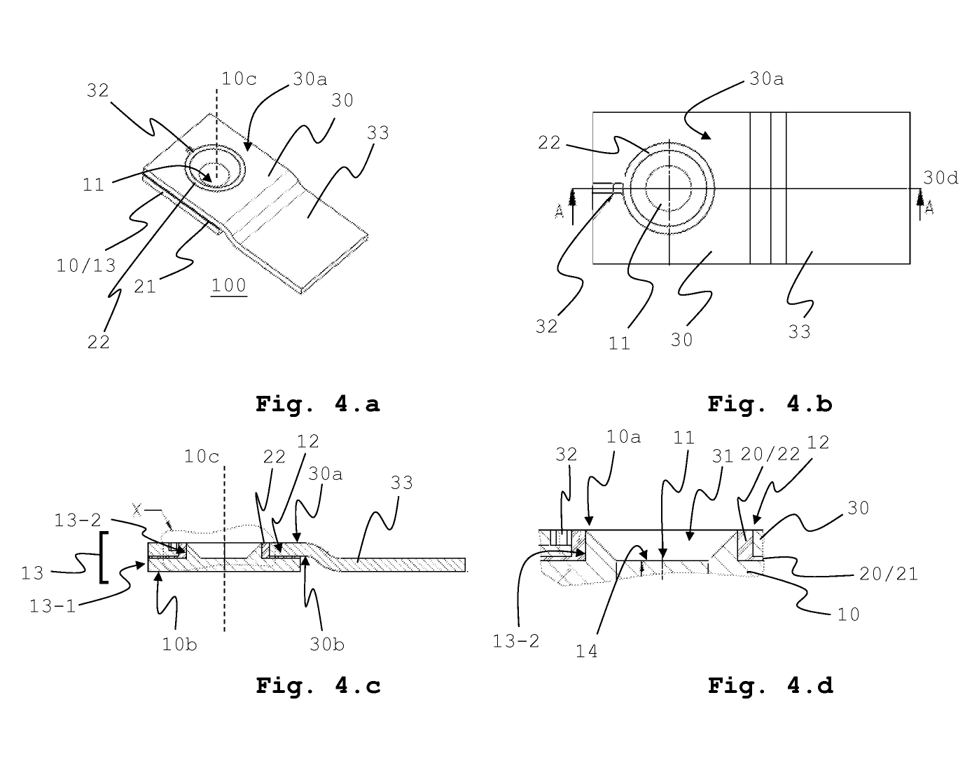

FIGS. 4.a to 4.d illustrate a first embodiment of a two-layered housing having a first and a second depression in the base body, and a connecting body mounted to a lateral surface of the base body, in a perspective view of the upper surface (FIG. 4.a), a plan view of the upper surface (FIG. 4.b), a cross-sectional view along longitudinal axis A-A (FIG. 4.c), and in an enlarged cross-sectional view of the region marked with X (FIG. 4.d).

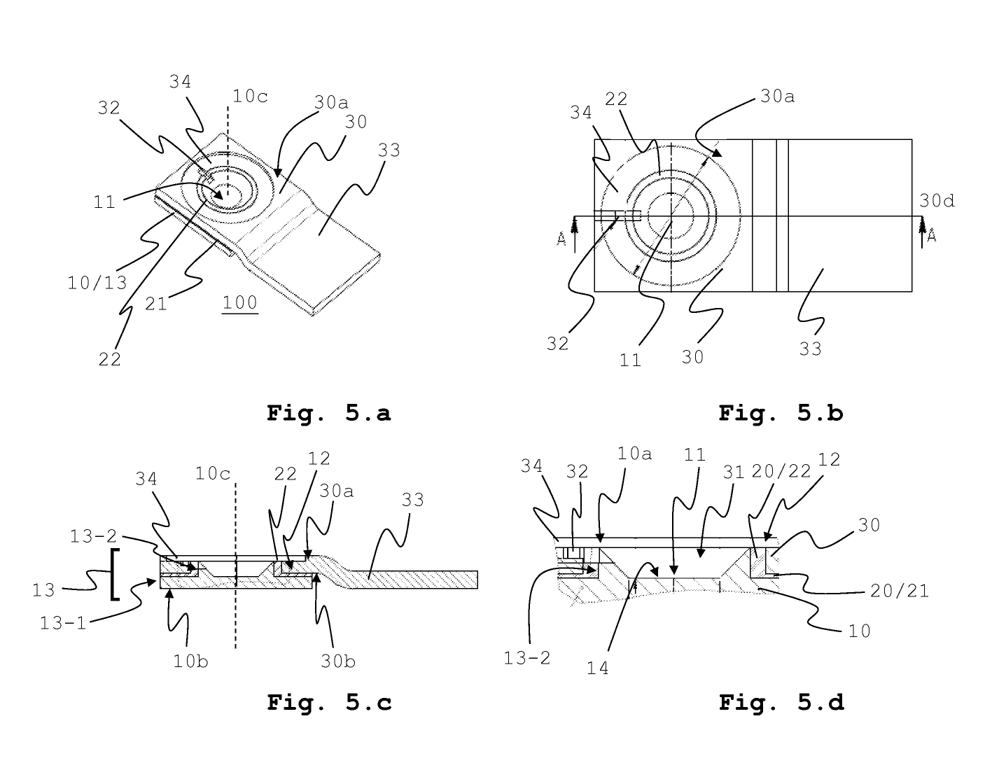

FIGS. 5.a to 5.d illustrate a second embodiment of a two-layered housing having a first and a second depression in the base body, and a connecting body mounted to a lateral surface of the base body, in a perspective view of the upper surface (FIG. 5.a), a plan view of the upper surface (FIG. 5.b), a cross-sectional view along longitudinal axis A-A (FIG. 5.c), and in an enlarged cross-sectional view of the region marked with X (FIG. 5.d).

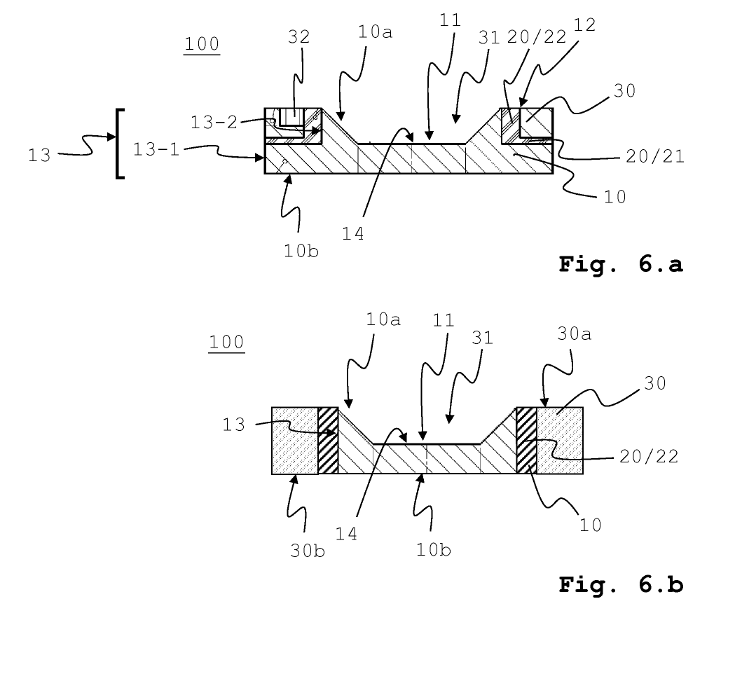

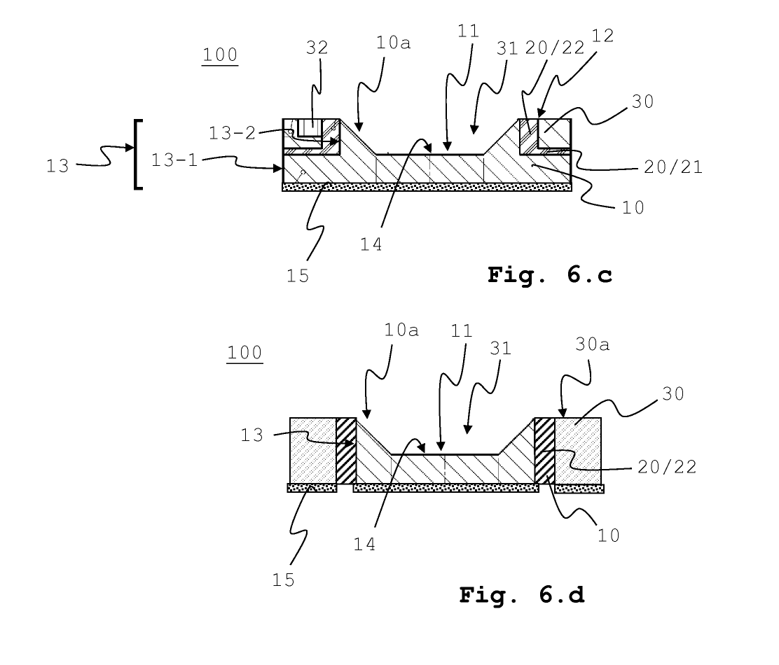

FIGS. 6.a to 6.d illustrate embodiments of a two-layered housing having a connecting body mounted to a lateral surface of the base body, in a cross-sectional view without (FIGS. 6.a and 6.b) and with an insulation layer (FIG. 6.c and 6.d).

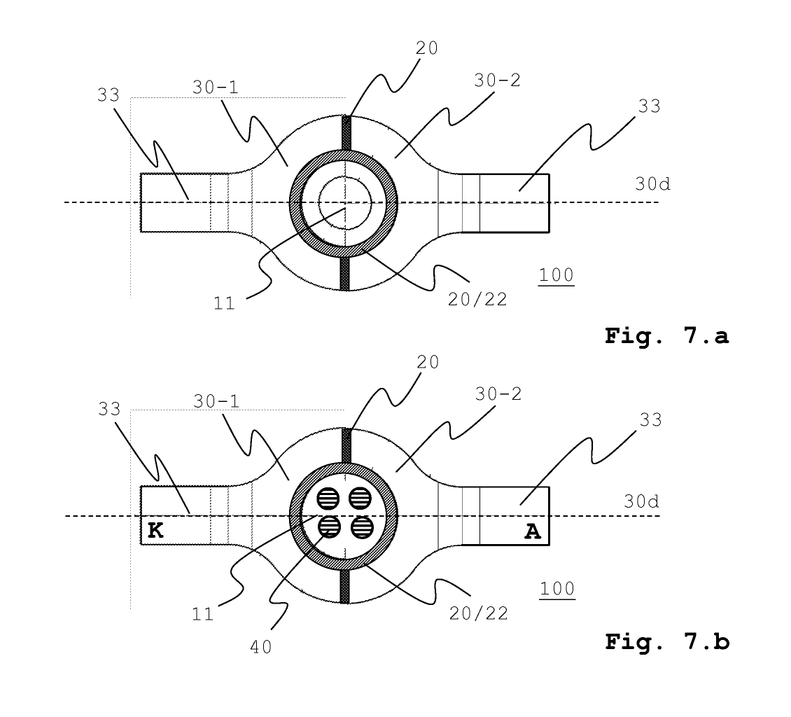

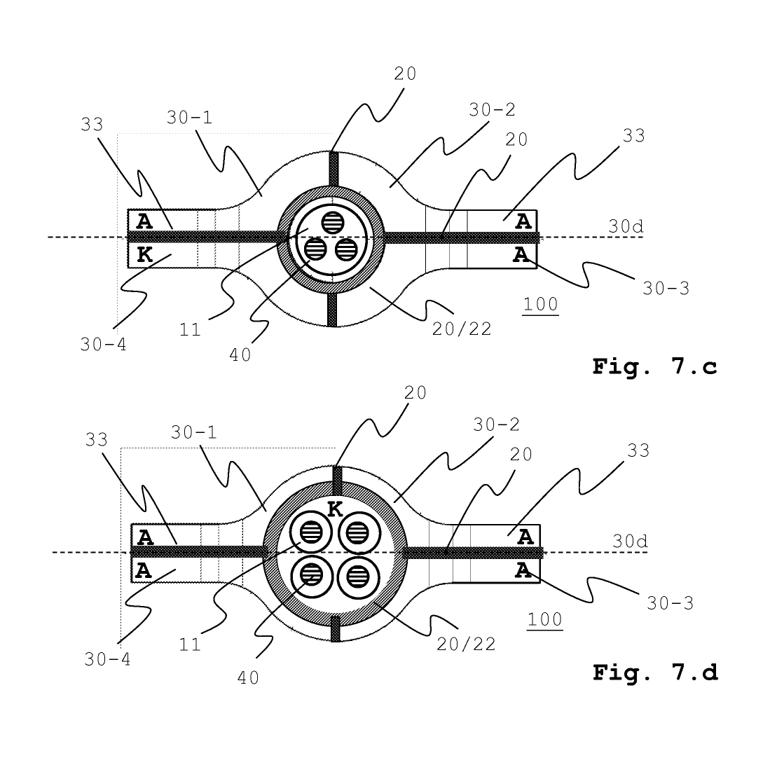

FIGS. 7.a to 7.d illustrate some embodiments of a two-layered housing having a segmented connecting body mounted to the base body, in a plan view of the upper surface.

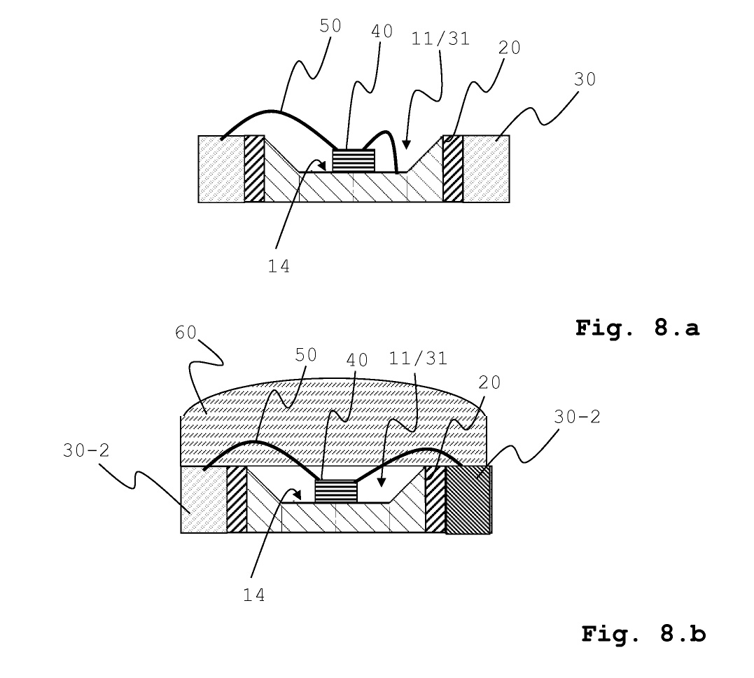

FIGS. 8.a and 8.b illustrate possible electrical connections for a single optoelectronic functional element disposed in the first depression.

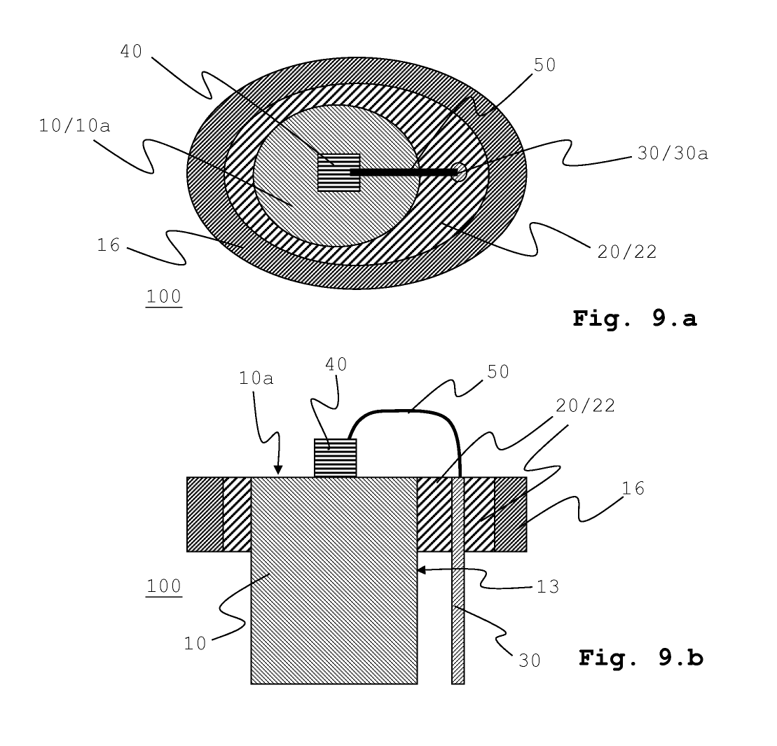

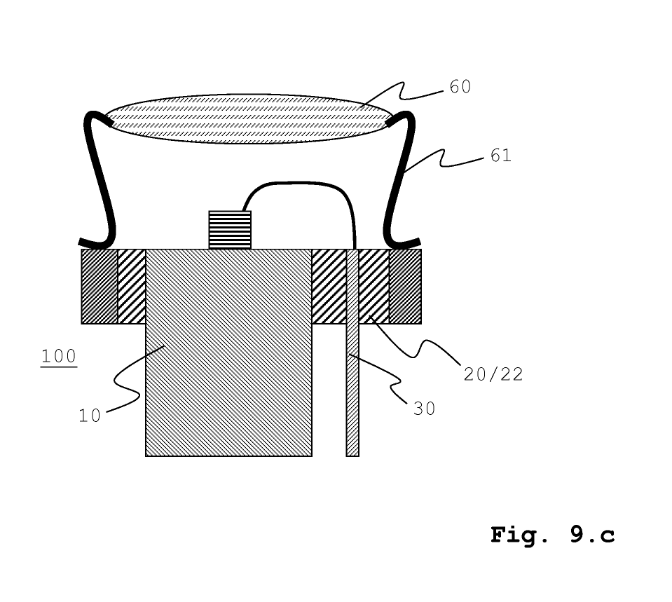

FIGS. 9.a to 9.c illustrate another embodiment of a two-layered housing comprising a connecting body mounted at a lateral side of the base body, in a plan view of the upper surface (FIG. 9.a), in a cross-sectional view (FIG. 9.b), and in a cross-sectional view with an end element superposed (FIG. 9.c).

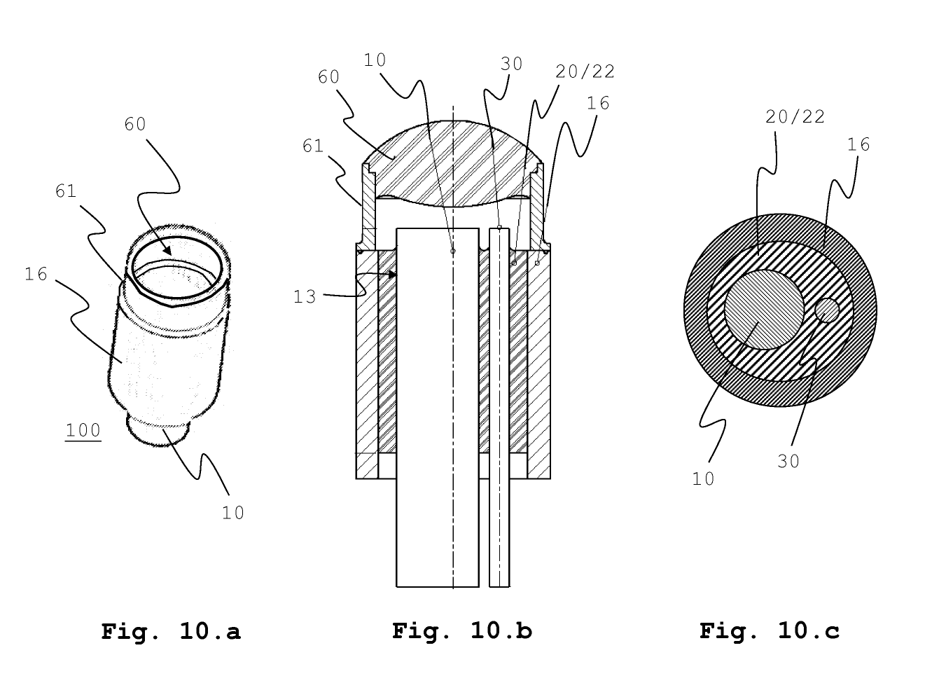

FIGS. 10.a to 10.c show a modified embodiment of a one-layered housing, in a perspective view (FIG. 10.a), in a cross-sectional view (FIG. 10.b), and in a plan view of the upper surface (FIG. 10.c).

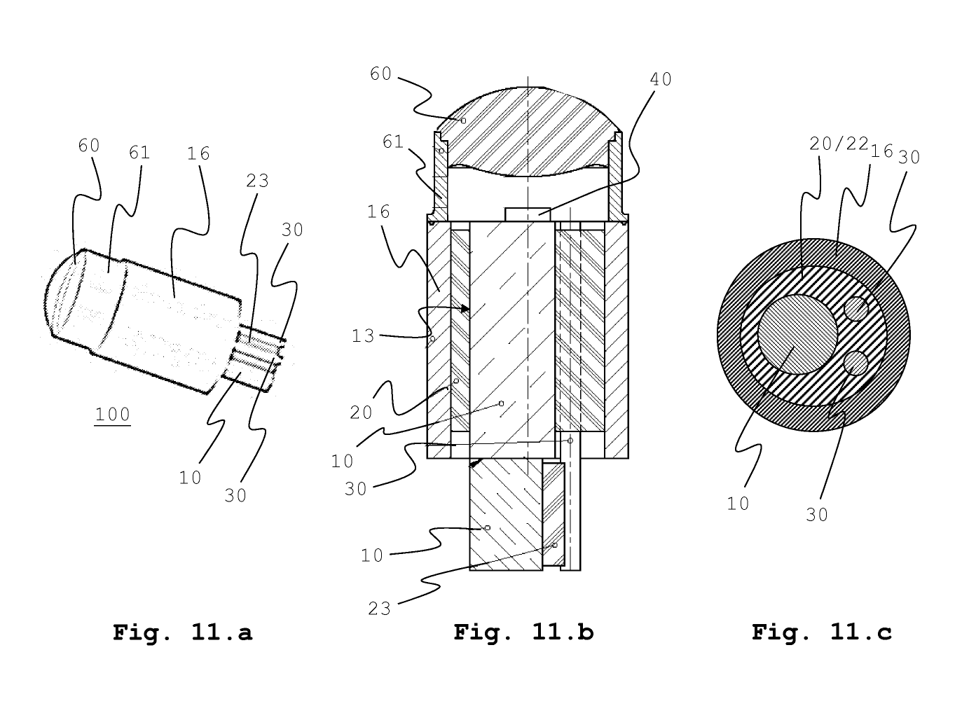

FIGS. 11.a to 11.c show a modified embodiment of a one-layered housing, in a perspective view (FIG. 11.a), in a cross-sectional view (FIG. 11.b), and in a plan view of the upper surface (FIG. 11.c).

### DETAILED DESCRIPTION OF THE INVENTION

FIGS. 1.a to 1.d show a first embodiment of a 2-layered or at least 2-layered housing 100 having a single, here a first depression 11 in the base body 10. A connecting body 30 is placed upon base body 10. Base body 10 and connecting body 30 are joined to each other by a material bond through a glass layer 20.

Base body 10 has an upper surface 10a, a lower surface 10b, and a lateral surface 13 or periphery 13, and a central axis 10c. In the example shown, the base body 10 has a square cross section. Its upper surface 10a has a first depression 11, for example provided by a recess 11. Depression 11 is preferably arranged centrally and/or coaxially to base body 10. Here, first depression 11 has a round, preferably circular cross section. However, the cross section may likewise be rectangular, preferably square. The diameter of first depression 11 increases, preferably continuously, starting from the bottom of first depression 11 towards the upper side thereof. First depression 11 has the shape of a truncated cone. However, it might also have the shape of a truncated pyramid. An optoelectronic functional element 40, not shown, is positioned in the first depression 11 or upon the bottom of first depression 11. In particular, functional element 40 is disposed in the center of first depression 11 and/or coaxially to base body 10 and/or to the first depression 11 (see FIGS. 8.a and 8.b).

Base body 10 is preferably implemented as a metallic plate, preferably a copper plate. A mounting area 14 for at least one optoelectronic functional element 40 is defined at the upper surface 10a of base body 10. Here, mounting area 14 is provided by the bottom of first depression 11 in the upper surface 10a of base body 10. In particular in view of production cost, base body 10 in particular including the first depression 11 and/or a second depression 12 and/or other modifications not or not yet shown herein, is produced by punching.

Connecting body 30 is arranged on base body 10, or upon the upper surface 10a of base body 10. Connecting body 30 has an upper surface 30a, a lower surface 30b, and a longitudinal axis 30d. Connecting body 30 is a metallic plate, preferably a copper plate. In the connecting body 30 a transmission zone 31 is provided for the radiation emitted and/or to be received by the optoelectronic functional element 40. The transmission zone 31 is preferably provided in connecting body 30 in form of a recess 31, or hole 31. Transmission zone 31 is preferably arranged in coaxial relationship to the first depression 11 in base body 10.

At an inner surface of transmission zone 31, a region 32 is provided for connecting a bonding wire 50, not shown, through which the optoelectronic functional element 40 is connectable. Preferably, this connection region 32 is implemented as a recess 32 in connecting body 30.

Transmission zone 31 has the shape of a straight cylinder of preferably circular cross section. The diameter of transmission zone 31, herein, is larger than the preferably upper diameter of the first depression 11 in base body 10.

Connecting body 30 has substantially the same dimensions as base body 10. Additionally, however, the connecting body 30 has a lateral extension 33, or tab 33, which extends beyond the lateral surface 13 of base body 10. Tab 33 is preferably flexible, or pre-bent as shown, so that for example an electrical connection may be established to a conductor trace of a circuit board upon which the housing 100 is placed in operating condition.

Especially in order to keep production cost low, the connecting body 30, in particular including the transmission zone 31 formed therein and/or the connection region 32 and/or tab 33 and/or including further modifications not or not yet shown herein, is produced by a punching process.

Between the upper surface 10a of base body 10 and the lower surface 30b of connecting body 30, glass layer 20 is disposed, which joins the base body 10 to the connecting body 30. The glass of glass layer 20 is a glass for joining base body 10 and connecting body 30. In a preferred embodiment of the invention, the glass is an alkali titanium silicate glass.

A first method step includes providing the base body 10 with first depression 11 and the connecting body 30 with transmission zone 31, connecting region 32, and tab 33. In a first variation of the method, a preform 20 is provided between base body 10 and connecting body 30. A preform 20 is cost efficient in manufacturing and easy to handle. Preform 20 has a central opening corresponding to the recess 31 in connecting body 30. Base body 10, connecting body 30, and glass strip 20 are aligned with each other. At least the preform 20 is heated, indirectly or directly. Base body 10 and connecting body 30 with preform 20 interposed therebetween are pressed together. Then, the housing 100 or composite structure that has been formed is cooled. In a second variation, the glass 20 is provided by dispensing. Dispensing enables to easily provide any size or shape of glass.

An optoelectronic functional element 40 placed in the first depression 11 is protected in the housing 100. If the functional element 40 is implemented as an LED, for example, the inner surface or lateral surface of first depression 11 in base body 10 and/or of the transmission zone 31 in connecting body 30 may have reflecting properties, in particular at least in sections thereof, in order to improve illumination. Therefore, the first depression 11 and/or the transmission zone 31 may be referred to as a reflector. Depending on the material and/or manner of manufacturing, the inner surface of depression 11 and/or of transmission zone 31 may already have sufficiently good reflective properties. Usually, however, reworking of the inner surface will be required. One way to achieve the reflective properties is by machining the inner surface, for example by polishing. As an alternative or in addition thereto, the inner surface may also be coated and/or covered, in sections thereof or completely, preferably with a metal. The metal for producing the coating and/or lining, is at least one material selected from a group consisting of silver, aluminum, nickel, palladium, and gold. The method for generating or producing the coating is at least one method selected from a group consisting of electro-plating, and vapor deposition, in particular PVD and/or CVD.

Once the optoelectronic functional element 40 has been installed, an optical component 60, such as a lens 60, may be disposed upon connecting body 30, for example. Thereby, some kind of cover is provided. Preferably, the optical component 60 is fixed in a manner so that the interior of housing 100 is hermetically sealed.

For the embodiments explained below, only the respective modifications as compared to the respective previous figures will be described, in order to avoid repetitions. For identical or similar features, reference is made to the respective aforementioned embodiments.

FIGS. 2.a to 2.d show a second embodiment of the present invention. As a modification when compared to the first embodiment of the invention shown in FIGS. 1.a to 1.d, an accommodating area 34 for an optical component 60 is additionally provided in the upper surface 30a of connecting body 30. In this manner, optical component 60 may be precisely and reliably placed on and joined to housing 100, in particular to connecting body 30, for example by gluing. Optical component 60 is for example a lens 60, in particular a glass lens. Accommodating area 34 is adapted to transmission zone 31. It is of substantially the same form or shape as transmission zone 31. In the variation shown, accommodating area 34 has a substantially round, preferably circular cross section, being provided by a depression 34, or recess 34, in the upper surface 30a of connecting body 30. Depression 34 has a larger cross-sectional dimension than the transmission zone 31 of connecting body 30. For example, depression 34 has an exemplary depth from about 0.1 to 1 mm. The supporting area preferably ranges from 0.5 mm to 20 mm.

FIGS. 3.a to 3.d show a third embodiment of the invention. As a modification to the embodiment shown in FIGS. 2.a to 2.c, the transmission zone 31 in connecting body 30 herein has a cross section which increases, preferably continuously, starting from the lower side 30b of connecting body 30 towards the upper side 30a thereof. Transmission zone 31 substantially has the shape of a truncated cone. If the inner surface or lateral surface of transmission zone 31 has reflecting properties, at least in sections thereof, transmission zone 31 in connecting body 30 may also be referred to as a reflector 31. Reflector 31 adjoins reflector 11 of base body 10. Reflector 11 in base body 10 and reflector 31 in connecting body 30 together form the reflector of the housing 100. The shapes of the two reflectors 11 and 31 essentially correspond to each other. The two reflectors 11 and 31 merge into one another. The dimensions and shape of the upper portion of reflector 11 in base body 10 substantially correspond to the dimensions and shape of the lower portion of reflector 31 in connecting body 30. For more details about the implementation of reflector 31 in connecting body 30 reference is made to the description of reflector 11 in base body 10.

In the embodiments described above, the base body 10 and the connecting body 30 are joined by a glass layer 20, which is substantially exclusively arranged between the upper surface 10a of base body 10 and the lower surface 30b of connecting body 30. By contrast, the embodiments described below illustrate a housing 100 in which the base body 10 and the connecting body 30 are joined, in particular additionally, by a glass layer 20 which is disposed between the lateral surface 13 of base body 10 and the connecting body 30 or the inner surface of the transmission zone 31 of connecting body 30.

FIGS. 4.a to 4.d show a first embodiment of a two-layered housing 100 having a first depression 11 in base body 10 for positioning and/or accommodating the functional element 40, and additionally having a second depression 12 in base body 10 for attaching and/or accommodating the connecting body 30. Connecting body 30 is mounted to the lateral surface 13 of base body 10, i.e. at the lateral side or periphery of base body 10.

The first depression 11 is again arranged in the center 10c of base body 10. However, the second depression 12 extends completely around the periphery of the first depression 11.

The second depression 12 may for example be seen in FIGS. 4.c and 4.d. However, depression 12 is not illustrated alone herein, as is for example first depression 11. Rather in the two figures, the second depression is already filled with the glass layer 20 and with connecting body 30.

Due to the circumferential second depression 12, the lateral surface 13 of base body 10 is defined by a segmented lateral surface 13. It is defined by a lower outer lateral surface 13-1 or lateral surface section 13-1, and by an upper inner lateral surface 13-2 or lateral surface section 13-2. Second depression 12, likewise, is preferably formed as a recess 12 in base body 10. In a plan view of base body 10, second depression 12 has a circular ring type geometry. The circular ring is delimited by the outer lateral surface 13-1 of base body 10 and by the inner lateral surface 13-2 of base body 10 or the outer surface of the wall which defines the reflector 11 in base body 10. In the present case, lateral surface 13, or periphery 13 of base body 10 is defined by lower section 13-1 and upper section 13-2. Upper section 13-2 is offset inwardly, towards the center, relative to lower section 13-1.

In a cross-sectional view, base body 10 may be described as some kind of a saucer. The inner, first depression 11 provides the reflector 11. The outer, second depression 12 provides a plateau type shoulder for placing the connecting body 30. First depression 11 and second depression 12 are separated by some kind of a wall, with the inner surface thereof defining the reflector 11 for the radiation emitted or to be received by optoelectronic functional element 40. The second depression 12 may substantially represent the supporting surface for the connecting body 30 at the base body.

In the present example, the inner side of transmission zone 31 of the connecting body 30 adjoins the inner upper section 13-2 of base body 10. In addition, sections of the lower surface 30b of connecting body 30 bear upon the upper surface 10a of base body 10 or upon the bottom of second depression 12.

Connecting body 30 and base body 10 are electrically insulated from each other by the glass layer 20 while being joined to each other by the glass layer 20. Glass layer 20, in particular in the joined state, is arranged between the upper inner lateral surface 13-2 of base body 10 and the inner surface of transmission zone 31 in connecting body 30 on the one hand, and between the upper surface 10a of base body 10 and the lower surface 30b of connecting body 30 on the other. As can be seen in the cross-sectional view, an L-shaped type of glass bonding is formed (see especially FIGS. 4.c and 4.d). A first leg 21 of the glass layer 20 extends substantially along the bottom of second depression 12, preferably in parallel thereto. A second leg 22 of glass layer 20 extends substantially transversely to the first leg 21 of glass layer 20, preferably perpendicular thereto. Second leg 22 extends along the inner lateral surface 13-2 of base body 10, preferably in parallel thereto. The width of second depression 12 is substantially represented by the first leg 21 of glass layer 20.

The height of connecting body 30 and/or the depth of second depression 12 and/or the height of glass layer 20 or 21 is/are dimensioned such that the upper surface 30a of connecting body 30 substantially flushes with the uppermost edge of upper surface 10a of base body 10.

An advantage of this embodiment of the invention is that the housing 100 can be provided with a low height. Another advantage results from the fact, that there is no glass seam nor any glass present in the reflector 11 and/or in the light transmission zone 31. This prevents any optional reflective properties of the reflector 11 from being adversely affected, for example by a dark glass. It should be noted that the opening 31 in connecting body 30 is still described as a transmission zone 31, even if it is no longer directly in the optical path and so cannot provide a reflector. That is because the functional element 40 or the radiation emitted or received by functional element 40 is still within the range of opening 31 of connecting body 30. The reflector 11 in base body 10 and the transmission zone 31 in connecting body 30 or the volumes thereof overlap or are arranged one above the other, preferably at least partially.

FIGS. 5.a to 5.d show a second embodiment of this variation. As a modification relative to the housing 100 shown in FIGS. 4.a to 4.d, an accommodating area 34 for an optical component 60 is additionally provided in the upper surface 30a of connecting body 30. For more details about accommodating area 34 reference is made to the description of FIGS. 2.a to 2.d.

Below, two further embodiments of a two-layered housing 100 are illustrated in FIGS. 6.a and 6.b, comprising first and second depressions, 11 and 12, in base body 10, and a connecting body 30 mounted at the lateral side of base body 10.

First, FIG. 6.a shows a housing 100 in which the base body 10 and the connecting body 30 are joined in the same manner as in the housing 100 illustrated in FIGS. 4.a to 4.d. In contrast thereto, connecting body 30 has no tab here. Connecting body 30 has substantially the same cross-sectional dimension and substantially the same shape as base body 10.

Furthermore, FIG. 6.b shows a housing 100 in which the connecting body 30 is secured to base body 10 only at the lateral side 13 thereof. Here, the two layers are not arranged one above the other, but side by side. The connecting body 30 is a body or component having an opening 31 or transmission zone 31 which has a cross-sectional shape that is adapted to the shape and/or dimensions of the base body 10 such that the connecting body 30 may accommodate the base body 10 in its interior or in its transmission zone 31. The inner diameter of connecting body 30 or of the transmission zone 31 in connecting body 30 is larger than the outer diameter of base body 10 and is selected such that a glass layer 20 or 22 may be disposed therebetween. In the present example, the connecting body 30 is some kind of a hollow cylinder or ring or a body having a cylindrical opening 31, which is pulled over the base body 10 which in the present case has a round, preferably circular shape.

Connecting body 30 is attached at the lateral side or periphery of base body 10. In this embodiment of housing 100, the joining glass layer 20 or 22 is only disposed between the outer lateral surface 13 of the base body and the inner lateral surface of the connecting body. As can be seen in the cross-sectional view, a kind of I-shaped glass bonding is formed. A ring-in-ring type system is formed around base body 10. Here, the bonding glass layer 20 or 22 defines a first ring, and the connecting body 30 defines a second ring. Both rings are arranged around base body 10. Here, connecting body 30 and glass layer 20 or 22 extend completely and/or continuously around the circumferential surface of base body 10 and around reflector 11.

FIGS. 6.c and 6.d show the same configurations as in FIGS. 6.a and 6.b. In addition, an insulation 15, in particular an insulating layer 15, is applied to the lower surface 10b of base body 10 and, if applicable, to the lower surface 30b of connecting body 30. In FIG. 6.c, the lower surface 10b of base body 10 is completely or substantially completely covered by insulation 15. In FIG. 6.d, by contrast, insulation 15 is segmented. The metallic components, here the lower surface 10b of base body 10 and the lower surface 30b of connecting body 30, are covered by insulation 15. In this manner, the lower surface of housing 100 may be kept electrically floating.

All embodiments illustrated so far have in common that the connecting body 30 extends completely or substantially completely or continuously around the circumference of the reflector 11 in base body 10 and/or around the transmission zone 31 formed in connecting body 30. The connecting body 30 is formed in one piece, or unitarily, in each case. It preferably provides a single electrical connection, for example for an anode or a cathode of an LED 40.

In FIGS. 7.a to 7.d, by contrast, connecting body 30 is now segmented, or is divided into segments 30-1 to 30-4 which are preferably electrically insulated from each other. A segmented connecting body 30 provides a plurality of connections, or consists of a plurality of connecting bodies 30-1 to 30-4 which are electrically insulated from each other. Segments 30-1 to 30-4 may be mounted to the base body according to the embodiments shown in FIG. 6.a or in FIG. 6.b.

In FIG. 7.a, the connecting body 30 comprises two parts. It is interrupted along the diameter of base body 10, in particular transversely, preferably perpendicularly, to the longitudinal axis of the housing 100 and preferably also to the longitudinal axis 30d of connecting body 30. Connecting body 30 is composed of two components, 30-1 and 30-2. As a further difference, the housing 100, or the connecting body 30 now has two tabs 33. Each of the two connecting bodies 30-1 and 30-2 has one tab 33. The tabs extend along the longitudinal axis 30d. Thus, two connections may be provided, for example for the anode and the cathode of an LED 40.

FIGS. 1.a through 7.a described so far illustrate some embodiments according to the invention in which only the housing 100 is shown, without a functional element 40. FIGS. 7.b to 7.d, by contrast, now illustrate embodiments with a single functional element 40 or with a plurality of functional elements 40 in a housing 100.

After having been installed in the housing 100 or placed upon the upper surface 10a of base body 10, in particular on the bottom of first depression 11, the functional element 40 will be in direct contact with base body 10. The functional element 40 may for example be adhered or soldered to the base body 10. Preferred solders that are used include lead-free soft solders. The adhesive is preferably a conductive adhesive, such as an epoxy enriched with silver. Therefore, direct contact also means a contact via an adhesive, a solder, or a binding agent.

FIG. 7.b shows an embodiment in which a plurality of functional elements 40 is disposed in a single reflector 11 or a single first depression 11, here four LEDs 40, by way of example. The four LEDs 40 are supplied by a common anode A and a common cathode K and thus are driven in common. The anode and cathode are preferably provided by the two tabs 33 of the segmented connecting body 30-1 and 30-2, respectively.

FIG. 7.c shows an embodiment in which a plurality of functional elements 40 is arranged in a single reflector 11 or a single first depression 11, here three LEDs 40, by way of example. The connecting body 30 is segmented into four connections 30-1 to 30-4 in this example. The three LEDs 40 may be driven individually. For example, segments 30-1 to 30-4 of connecting body 30 provide three separate anodes A and one shared cathode K.

FIG. 7.d shows an embodiment in which a plurality of functional elements 40, here four LEDs 40 by way of example, are arranged in a plurality of reflectors 11. In this example, four reflectors 11 are provided in the base body 10. Each reflector 11 has associated therewith at least one LED 40. The four LEDs 40 may be driven individually. For example, four separate anodes A may be provided by the four segments 30-1 to 30-4 of connecting body 30, and a shared cathode K may be provided by the upper surface 10a of base body 10 or by a bottom 11 of reflectors 11.

FIGS. 8.a and 8.b illustrate possible electrical connections for a single optoelectronic functional element 40 positioned in a reflector 11.

In FIG. 8.a, the functional element 40, in particular an LED 40, may be electrically connected via two terminals, namely anode A and cathode K, via its front face and its back face. Functional element 40 is connected through a wire 50 (so called wire bonding) with the supply lines or the connecting body 30 of the housing 100. In this case, a first connection is provided by the connecting body 30. A second connection is provided by the upper surface 10a of the metallic base body 10, for example by the bottom of reflector 11.

FIG. 8.b shows the configuration illustrated in FIG. 8.a with a lens 60 applied to the housing 100 as an end element 60. Lens 60 is for example provided by placing a glass lens, or by applying a drop of a material which is transparent for the relevant range of wavelengths, for example of silicone. While FIG. 8.a illustrates an embodiment of a functional element 40 which may be contacted via its front face and its back face, FIG. 8.b shows an embodiment in which the functional element 40 may only be contacted via its front face. For this purpose, herein, the connecting body 30 is divided into two segments, 30-1 and 30-2. A first connection is provided by segment 30-1 shown on the left. A second connection is provided by segment 30-2 shown on the right.

Finally, FIGS. 9.a to 9.c show another embodiment of a housing 100 with a connecting body 30 secured to the lateral surface 13 of base body 10. Here, the connecting body 30 is implemented as a contact pin 30, by way of example. Contact pin 30 is an elongated metal component having a very reduced cross-sectional area relative to the length thereof. It is a needle-shaped or nail-like component. Contact pin 30 is provided with an I-shape or as a substantially straight pin. A metallic wire is also to be understood as a contact pin. The cross-sectional area of the contact pin generally ranges from about 0.1 mm² to about 16 mm², preferably up to not more than about 3 mm², more preferably up to not more than about 0.8 mm².

The contact pin or connecting body 30 is secured to the base body at the lateral side or periphery thereof. In this variation of the housing 100, glass layer 20 or 22 is disposed on outer lateral surface 13. Glass layer 20 only covers sections of lateral surface 13. Base body 10 extends downwards beyond glass layer 20. The contact pin or connecting body 30 is disposed within or inside the glass layer 20, or is embedded therein, at least partially. It has a length that is larger than the height of glass layer 20. In an upper portion, connecting body 30 is completely surrounded by glass layer 20 around its circumferential surface. In a lower portion by contrast, connecting body 30 is completely exposed. On the outer surface of glass layer 20, a tubular portion or sleeve 16 is positioned. Sleeve 16 extends completely around the circumferential surface of glass layer 20, or around the circumference of housing 100. Sleeve 16 is preferably a metallic sleeve, for example of stainless steel. In this manner it is possible to keep the outer surface of housing 100 electrically floating. Sleeve 16 forms a potential-free outer conductor, or a shield.

The two layers of base body 10 and sleeve 16 are not arranged one above the other here, but side by side. In the cross-sectional view it can be seen that some kind of an I-shaped glass bonding is formed. A ring-in-ring type system is formed around base body 10. Here, the bonding glass layer 20 or 22 defines a first ring, and sleeve 16 defines a second ring. Both rings are arranged around base body 10. Here, glass layer 20 or 22 and sleeve 16 extend completely and/or continuously around the circumference of base body 10. By way of example, housing 100 has a round cross section herein, in particular an oval one. However, the cross section may likewise be generally circular, or may be polygonal.

FIG. 9.c corresponds to FIG. 9.b. Additionally, however, a lens is disposed above the upper surface 10a of base body 10, as an end element 60. The lens is secured spaced apart from the upper surface 10a of base body 10 by means of a holder 61. Holder 61 is provided, for example, by a further tubular portion or a further sleeve. Here, holder 61 is placed upon the upper surface of sleeve 16.

FIGS. 10.a to 10.c show an embodiment modified as compared to that of FIGS. 9.a to 9.c, of a one-layered housing 100. First, the cross section of housing 100 is not oval but circular. Moreover, base body 10 and connecting body 30 do no longer terminate at the upper surface of sleeve 16 and the upper surface of glass layer 20. Rather, base body 10 and connecting body 30 extend upwardly and downwardly, along the longitudinal axis of housing 100, beyond sleeve 16 and beyond glass layer 20. As a result, they are easily contacted. FIG. 10.c shows a view of the upper surface of housing 100 without components 60 and 61. Base body 10 and/or connecting body 30 extend beyond the lower surface of sleeve 16 by about 1 mm to about 10 mm, preferably by not more than about 5 mm. Preferably, the height and/or diameter of sleeve 16 ranges from about 3 mm to about 10 mm.

FIGS. 11.a to 11.c show another modified embodiment of a one-layered housing 100. In this embodiment, two connecting bodies 30 are provided. In combination with base body 10, this allows to separately drive two LEDs 40, for example. Base body 10 and the two connecting bodies 30 extend upwardly beyond glass layer 20, but terminate with sleeve 16. Base body 10 consists of two parts in this example. It is provided by an upper body and a lower body. Between the lower body or portion of base body 10 and the two connecting bodies 30, a further insulation 23 is provided, for example of glass.

The housings 100 shown in FIGS. 9.a through 11.c are particularly suitable for plug socket applications. For being connected, the downwardly extending base body 10 and the downwardly extending connecting body/bodies 30 may simply be plugged into a socket which provides the power supply, for example. This is for instance useful for an application of an LED as a lamp.

It will be apparent to those skilled in the art that the described embodiments are to be understood as examples. The invention is not limited to these embodiments but may be varied in many ways without departing from the spirit of the invention. Features of individual embodiments and the features described in the general part of the specification may be combined among each other and with each other.

### LIST OF REFERENCE NUMERALS

10 Base body
10a Upper surface of base body
10b Lower surface of base body
10c Central axis of base body
11 First depression, or reflector in the base body
12 Second depression, or accommodating region for connecting body in the base body
13 Lateral surface or periphery of base body
13-1 Outer lateral surface or lateral surface section of base body
13-2 Inner lateral surface or lateral surface section of base body
14 Mounting area for a functional element
15 Insulation, or insulating layer
16 Sleeve or sheath
20 Glass layer or glass for joining and insulating
21 First leg of glass layer
22 Second leg of glass layer
23 Insulation, or further glass layer
30 Connecting body
30a Upper surface of connecting body
30b Lower surface of connecting body
30d Longitudinal axis of connecting body
30-1 to 30-4 Segments of connecting body
31 Transmission zone, or opening, or reflector in connecting body
32 Connection region in connecting body, in particular for a bonding wire
33 Connection tab, or tab for connecting, in connecting body
34 Accommodating area for an optical component or an end element in connecting body
40 Functional element, or LED
50 Connecting means, or wire, or bonding wire
60 End element, or optical component, or lens
61 Holder for end element
100 Housing
A Anode
B Cathode

1-17. (canceled)

18. An housing for accommodating an optoelectronic functional element, comprising:
a base body having an upper surface that at least partially defines a mounting area for the optoelectronic functional element so that said base body forms a heat sink for the optoelectronic functional element, the base body further having a lower surface and a lateral surface; and
at least one connecting body for the optoelectronic functional element, the at least one connecting body being joined to the base body at least by one glass layer,
wherein the at least one connecting body is arranged at the lateral surface of the base body and at least partially extends along a circumferential surface of the base body.

19. The housing as claimed in claim 18, wherein at least the upper surface has at least one first depression with a bottom that provides the mounting area for the optoelectronic functional element.

20. The housing as claimed in claim 18, wherein the base body is made of metal and the connecting body is electrically insulated from the base body.

21. The housing as claimed in claim 20, wherein the glass layer is disposed between the lateral surface of the base body and the connecting body, at least in sections thereof.

22. The housing as claimed in claim 19, wherein the upper surface has at least one second depression that at least partially extends around a periphery of the first depression so that the lateral surface of the base body is defined by a lower outer lateral surface and an upper inner lateral surface.

23. The housing as claimed in claim 22, wherein the second depression provides an accommodating region for the at least one connecting body and the connecting body at least partially rests on a bottom of the second depression.

24. The housing as claimed in claim 22, wherein the second depression provides an accommodating region for the connecting body and the connecting body adjoins the inner lateral surface, the outer lateral surface of the base body, and combinations thereof.

25. The housing as claimed in claim 18, wherein the at least one connecting body has a transmission zone that extends over a location selected from the group consisting of the first depression, the mounting area, and combinations thereof.

26. The housing as claimed in claim 25, wherein the at least one connecting body is arranged in a location selected from the group consisting of the upper surface of the base body, an inner side of the transmission zone, the lateral surface of the base body, and any combinations thereof.

27. The housing as claimed in claim 25, wherein the transmission zone has a diameter that increases starting from a lower side of the transmission zone towards an upper side of the transmission zone.

28. The housing as claimed in claim 25, wherein the transmission zone has an inner surface of having reflecting properties, at least sections thereof to form a reflector for the optoelectronic functional element.

29. The housing as claimed in claim 18, wherein the at least one connecting body is segmented into segments so that a plurality of connections can be provided for the optoelectronic functional element placed upon the base body.

30. The housing as claimed in claim 29, wherein the segments are spaced from each other or are electrically insulated from each other by the glass layer.

31. The housing as claimed in claim 18, wherein the at least one connecting body at least partially extends beyond the base body and forms at least one connection tab.

32. The housing as claimed in claim 18, further comprising at least one mounting area for a bonding wire is provided in a location selected from the group consisting of the base body, the at least one connecting body, and combinations thereof.

33. The housing as claimed in claim 18, wherein the first depression has a diameter that increases starting from a bottom of the first depression on which the optoelectronic functional element is positionable towards an upper side of the first depression.

34. The housing as claimed in claim 18, wherein the first depression has an inner surface of having reflecting properties, at least sections thereof to form a reflector for the optoelectronic functional element.

35. The housing as claimed in claim 18, further comprising an element selected from the group consisting of an end element applied to the upper surface of the base body, an end element applied to an upper surface of the connecting body, an optical component applied to the upper surface of the base body, an optical component applied to an upper surface of the connecting body, an insulation applied at least to the lower surface of the base body, a sleeve disposed at the lateral side of the base body and at least partially extending around a circumferential surface of the base body, and combinations thereof.

36. An optoelectronic component comprising the housing as claimed in claim 18 further comprising at least one radiation emitting or radiation receiving optoelectronic functional element arranged in the housing.

37. An illumination device comprising the optoelectronic component as claimed in claim 36.

38. An illumination device comprising the housing as claimed in claim 18.

39. An array comprising a plurality of housings as claimed in claim 18.

40. A method for producing an optoelectronic functional element housing, comprising:
providing at least one base body having an upper surface that at least partially defines a mounting area for and forms a heat sink for the optoelectronic functional element, the base body having at least one first depression in an upper surface, the at least one first depression having a bottom which provides the mounting area for the optoelectronic functional element;
providing at least one connecting body for the optoelectronic functional element with glass between the base body and the connecting body so that the glass is between a lateral surface of the base body and the at least one connecting body;
heating the glass until it reaches a viscosity at which it adheres such that a composite structure is formed with the at least one connecting body attached, at least in sections, to the lateral surface of the base body; and
cooling the glass so that the base body and the at least one connecting body form a material bond through at least one glass layer formed of the cooled glass.

41. The method as claimed in claim 40, wherein the glass electrically insulates the base body made of metal from the at least one connecting body.

42. An housing for accommodating an optoelectronic functional element, comprising:
a base body having an upper surface that at least partially defines a mounting area for the optoelectronic functional element so that said base body forms a heat sink for the optoelectronic functional element, the base body further having a lower surface and a lateral surface; and
at least one connecting body for the optoelectronic functional element, the at least one connecting body being joined to the base body at least by one glass layer,
wherein at least the upper surface has at least one first depression with a bottom that provides the mounting area for the optoelectronic functional element.

43. The housing as claimed in claim 42, wherein the base body is made of metal and the connecting body is electrically insulated from the base body.

44. The housing as claimed in claim 43, wherein the glass layer is disposed between the upper surface of the base body and a lower surface of the connecting body, at least in sections thereof.
